(19) United States
(12) Patent Application Publication
(10) Pub. No.: US 2026/0211281 A1
(43) Pub. Date: Jul. 23, 2026

(54) DISPLAY DEVICE AND OPTICAL MODULE

(71) Applicant: WISTRON CORP., New Taipei City (TW)

(72) Inventors: RUMING ZHAO, New Taipei City (TW); JUNJIE ZHU, New Taipei City (TW); ZHIHUA LIU, New Taipei City (TW); YAOCHEN YANG, New Taipei City (TW)

(21) Appl. No.: 19/068,228

(22) Filed: Mar. 3, 2025

(30) Foreign Application Priority Data
Jan. 17, 2025 (CN) 202510081010.0

(51) Int. Cl. G02F 1/1335; G02F 1/1333

(52) U.S. Cl. CPC G02F 1/133553; G02F 1/133314

(57) ABSTRACT

A display device includes a casing assembly, an optical module and a display panel. The casing assembly includes a window surrounded by a bezel. The optical module is disposed in the casing assembly and includes an optical assembly, a reflective film and a receiver assembly. The reflective film is located farther away from the window than the optical assembly. The reflective film is provided with a plurality of light transmission holes, and the light transmission holes is located in a visible area where the window is projected. The receiver assembly is located at one side of the reflective film located farther away from the optical assembly, and the receiver assembly corresponds to the light transmission holes. The display panel is disposed in the casing assembly and located closer to the window than the optical assembly.

### CROSS-REFERENCE TO RELATED APPLICATIONS

This non-provisional application claims priority under 35 U.S.C. § 119(a) on Patent Application No(s). 202510081010.0 filed in China on Jan. 17th, 2025, the entire contents of which are hereby incorporated by reference.

### TECHNICAL FIELD

The disclosure relates to a display device and an optical module.

### BACKGROUND

In a current display device available on the market, in order for the display device to receive optical signals transmitted by a remote control and be controlled by it, the receiver for receiving the optical signals is generally disposed at the bottom of the bezel of the display device. However, arranging the receiver at the bottom of the bezel results in the bottom of the bezel being significantly wider than the other parts of the bezel (such as side parts or the top part), making it impossible to achieve a narrow bezel design. In view of this, researchers in this field are actively working to resolve the aforementioned issue.

### SUMMARY

The disclosure provides a display device and an optical module which can achieve a narrow bezel design.

One embodiment of the disclosure provides a display device. The display device includes a casing assembly, an optical module and a display panel. The casing assembly includes a window surrounded by a bezel. The optical module is disposed in the casing assembly and includes an optical assembly, a reflective film and a receiver assembly. The reflective film is located farther away from the window than the optical assembly. The reflective film is provided with a plurality of light transmission holes, and the light transmission holes is located in a visible area where the window is projected. The receiver assembly is located at one side of the reflective film located farther away from the optical assembly, and the receiver assembly corresponds to the light transmission holes. The display panel is disposed in the casing assembly and located closer to the window than the optical assembly.

Another embodiment of the disclosure provides an optical module. The optical module includes an optical assembly, a reflective film and a receiver assembly. The reflective film is located at one side of the optical assembly, the reflective film is provided with a plurality of light transmission holes, and the light transmission holes are located in a visible area of the reflective film. The receiver assembly is located at one side of the reflective film located farther away from the optical assembly, and the receiver assembly corresponds to the light transmission holes.

Still another embodiment of the disclosure provides an optical module. The optical module is used to be cooperated with a receiver assembly. The optical module includes an optical assembly and a reflective film. The reflective film is located at one side of the optical assembly, the reflective film is provided with a plurality of light transmission holes, the light transmission holes are located in a visible area of the reflective film, and the receiver assembly is used to receive light through the light transmission holes.

According to the display device and the optical module as discussed in the above embodiments, the receiver assembly is disposed in the casing assembly and located at one side of the reflective film located farther away from the optical assembly, and the receiver assembly corresponds to the light transmission holes in the visible area of the reflective film where the window is projected. This configuration allows the receiver assembly to receive light that penetrates through the display panel, the optical assembly and the reflective film. As a result, the receiver assembly is not installed on the bezel of the casing assembly, and thus there is no need to increase the width of the bezel to accommodate the receiver assembly, which contributes to achieve the narrow bezel requirement of the display device.

### BRIEF DESCRIPTION OF THE DRAWINGS

The present disclosure will become better understood from the detailed description given herein below and the accompanying drawings which are given by way of illustration only and thus are not intending to limit the present disclosure and wherein:

FIG. 1 is a perspective view of a display device according to a first embodiment of the disclosure;

FIG. 2 is an exploded view of the display device in FIG. 1;

FIG. 3 is a cross-sectional view of the display device in FIG. 1;

FIG. 4 is a front view of the display device in FIG. 1 when a display panel and an optical assembly are omitted;

FIG. 5 a partial enlarged view of an area X in FIG. 4;

FIG. 6 is a partial perspective view of a reflective film according to a second embodiment of the disclosure; and

FIG. 7 is a partial exploded view of the reflective film in FIG. 6.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the present disclosure, such as technical and scientific terms, have its own meanings and can be comprehended by those skilled in the art, unless the terms are additionally defined in the present disclosure. That is, the terms used in the following paragraphs should be read on the meaning commonly used in the related fields and will not be overly explained, unless the terms have a specific meaning in the present disclosure.

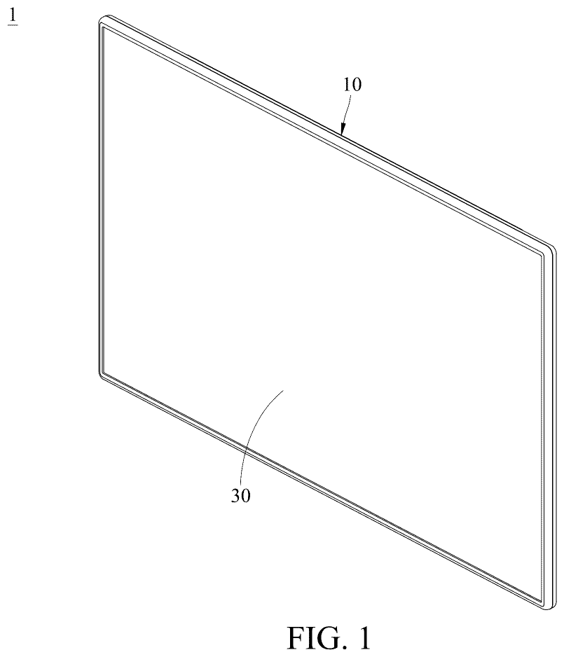

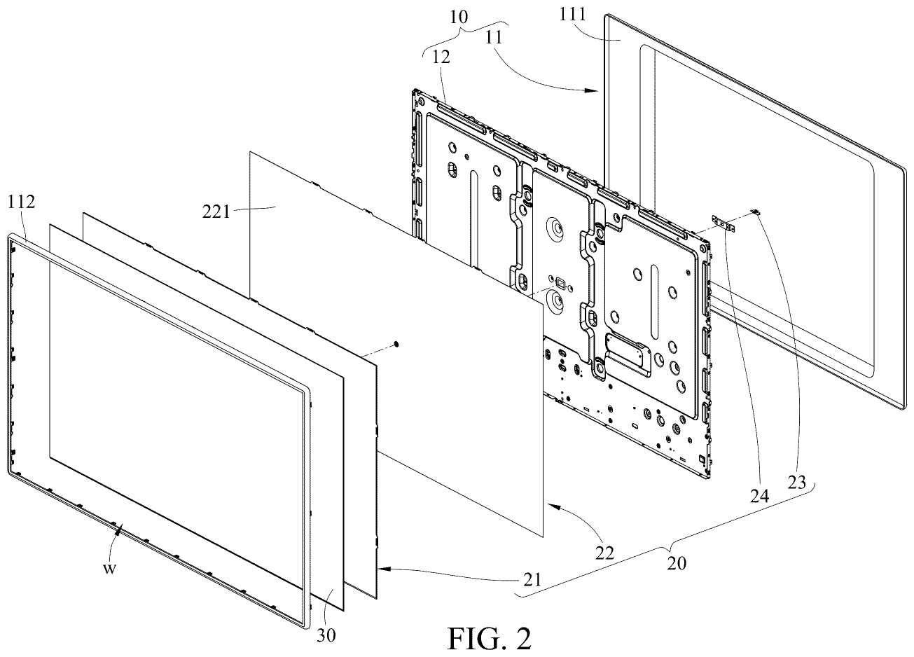

Referring to FIGS. 1 and 2, FIG. 1 is a perspective view of a display device according to a first embodiment of the disclosure, and FIG. 2 is an exploded view of the display device in FIG. 1.

In this embodiment, the display device 1 is, for example, a liquid crystal display device. The display device 1 includes a casing assembly 10, an optical module 20 and a display panel 30.

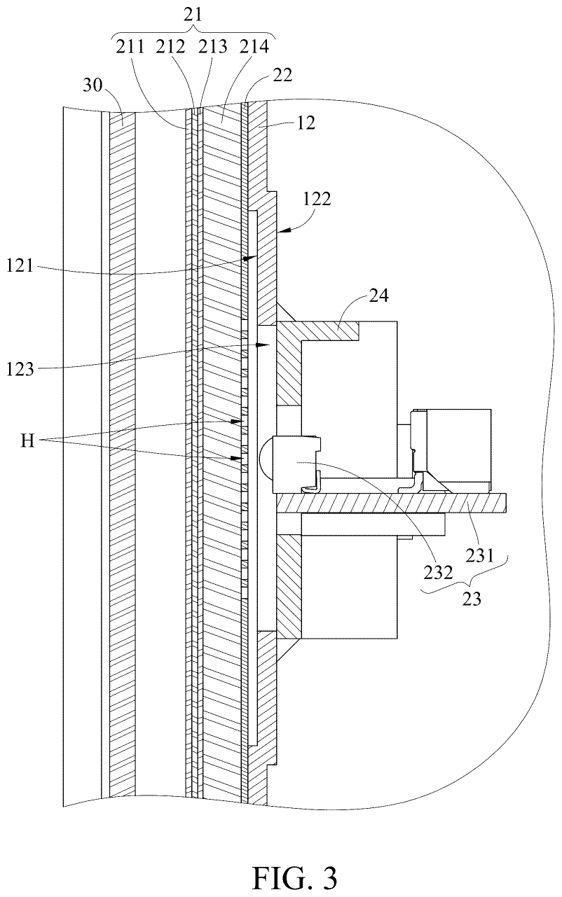

Then, referring to FIGS. 2 and 3, FIG. 3 is a cross-sectional view of the display device in FIG. 1.

The casing assembly 10 includes a casing 11 and a support component 12. The casing 11 includes a back cover 111 and a bezel 112. The back cover 111 is connected to the bezel 112. The bezel 112 surrounds and forms a window W. The support component 12 is fixed to the casing 11. The support component 12 includes a first surface 121, a second surface 122 and a through hole 123. The first surface 121 faces the window W and faces way from the second surface 122, and the through hole 123 penetrates through the first surface 121 and a second surface 122.

The optical module 20 is disposed in the casing 11. The optical module 20 includes an optical assembly 21, a reflective film 22 and a receiver assembly 23. In addition, the optical module 20 may further include a mount bracket 24.

The optical assembly 21 is located closer to the window W than the support component 12. The optical assembly 21, for example but not limited to, includes two prism sheets 211 and 212, a diffuser sheet 213 and a light guide plate 214. The prism sheets 211 and 212, the diffuser sheet 213 and the light guide plate 214 are sequentially arranged along a direction from the window W toward the support component 12. The reflective film 22 is located farther away from the window W than the optical assembly 21, the reflective film 22 is located between the light guide plate 214 of the optical assembly 21 and the support component 12, and the reflective film 22 is disposed on the first surface 121 of the support component 12.

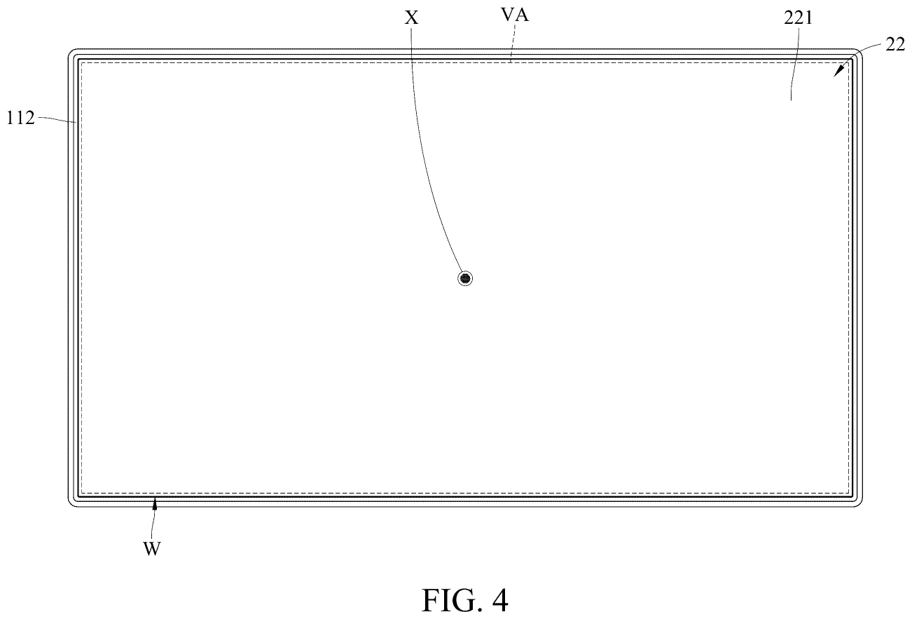

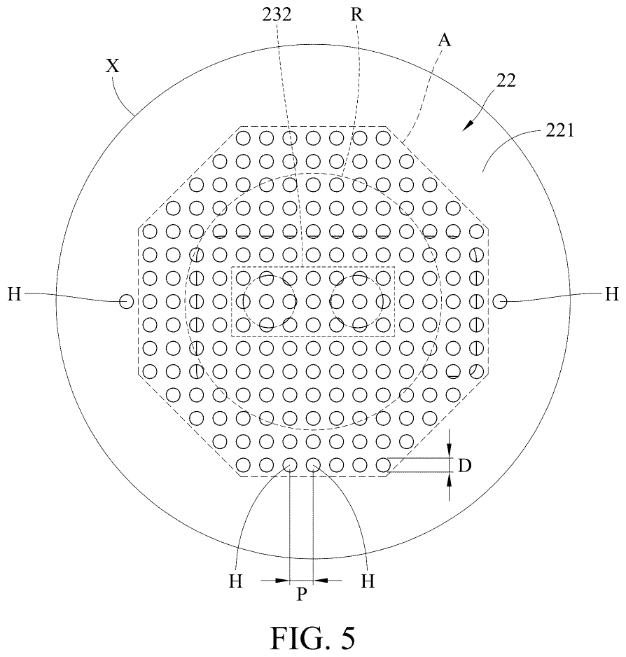

Then, referring to FIGS. 3 to 5, FIG. 4 is a front view of the display device in FIG. 1 when a display panel and an optical assembly are omitted, and FIG. 5 a partial enlarged view of an area X in FIG. 4.

The reflective film 22 is provided with a plurality of light transmission holes H. The light transmission holes H are located in a visible area VA of the reflective film 22 where the window W is projected. The following descriptions will exemplarily introduce the structure of the reflective film 22. The reflective film 22 includes a main portion 221, and the light transmission holes H are directly provided on the main portion 221. The main portion 221 of the reflective film 22 includes an arrangement area A. The arrangement area A is located in a central area of the main portion 221. The arrangement area A is a polygonal area, such as an octagonal area. Two of the light transmission holes H are located outside the arrangement area A and are located at two opposite sides of the arrangement area A, and the others of the light transmission holes H are located in the arrangement area A. In other words, the light transmission holes H surround the arrangement area A on the reflective film 22. The light transmission holes H are arranged in an array. A distance P between centers of two of the light transmission holes H located closest to each other is not greater than 1.0 mm; that is, the distance P between the centers of two of the light transmission holes H located closest to each other, either horizontally or vertically, is not greater than 1.0 mm. Hole diameters D of the light transmission holes H is not smaller than 0.6 mm and is not greater than 0.8 mm.

The receiver assembly 23, for example, includes a circuit board 231 and a receiver 232 disposed on the circuit board 231. The circuit board 231 is fixed to the second surface 122 of the support component 12 via the mount bracket 24. The receiver 232 corresponds to the light transmission holes H of the reflective film 22 through the through hole 123. An area R where a reception range of the receiver 232 projected onto the reflective film 22 is overlapped with the arrangement area A surrounded by the light transmission holes H, and the area R is smaller than the arrangement area A.

As shown in FIGS. 2 and 3, the display panel 30 is, for example, a liquid crystal display panel. The display panel 30 is disposed in the casing 11 and is located closer to the window W than the optical assembly 21.

In this embodiment, the receiver assembly 23 is used to receive light emitted from a remote control. For example, the remote control is an infrared remote control, and the receiver assembly 23 is an infrared receiver assembly. Infrared light emitted by the remote control penetrates through the display panel 30, the optical assembly 21 and the light transmission holes H of the reflective film 22 and is received by the receiver 232 of the receiver assembly 23.

In this embodiment, the receiver assembly 23 is disposed in the casing assembly 10 and located at one side of the reflective film 22 located farther away from the optical assembly 21, and the receiver assembly 23 corresponds to the light transmission holes H in the visible area VA of the reflective film 22 where the window W is projected. This configuration allows the receiver assembly 23 to receive light that penetrates through the display panel 30, the optical assembly 21 and the reflective film 22. As a result, the receiver assembly 23 is not installed on the bezel 112 of the casing assembly 10, and thus there is no need to increase the width of the bezel 112 to accommodate the receiver assembly 23, which contributes to achieve the narrow bezel requirement of the display device 1.

In this embodiment, the arrangement of the light transmission holes H in an array allows light to pass through more easily compared to a reflective film without light transmission holes. This enables the receiver 232 to receive light from a greater distance, thereby meeting requirements. According to simulation results, in a display device with a reflective film that has no light transmission holes, a receiver can receive light from a maximum distance of only 1.8 meters from the front and 0.6 meters from the left and right sides. In contrast, in the display device 1 of this embodiment, which includes the reflective film 22 with light transmission holes H, the receiver 232 can receive light from a maximum distance of 10 meters from the front and 6 meters from the left and right sides.

Compared to a reflective film with a single large-sized light transmission hole, the arrangement of the light transmission holes H in an array of this embodiment helps to prevent the display device 1 from exhibiting visibly noticeable black spot in a displayed image, thereby maintaining image quality. Furthermore, the hole diameters D of the light transmission holes H are not greater than 0.8 mm, which can further prevent the occurrence of visibly noticeable black spot in the displayed image of the display device 1.

In this embodiment, the hole diameters D of the light transmission holes H are not smaller than 0.6 mm, which facilitates the processing and formation of the light transmission holes H.

In this embodiment, the distances P between the centers of two closest light transmission holes H is not greater than 1.0 mm, which enables the light reception of the receiver 232 to meet the requirements.

Note that the sizes of the hole diameters D of the light transmission holes H are not limited to the aforementioned range. If other structures can prevent the occurrence of the black spot in the image, or if the manufacturing process allows for the easy formation of smaller light transmission holes H, the hole diameters of the light transmission holes H may be greater than 0.8 mm or smaller than 0.6 mm. Additionally, the distance P between the centers of two closest light transmission holes H is not limited to being not greater than 1.0 mm and can be adjusted as required. Furthermore, the arrangement of the light transmission holes H is not restricted to being in an array configuration and may be adjusted according to actual requirements.

In this embodiment, the area R where the reception range of the receiver 232 projected onto the reflective film 22 is overlapped with the arrangement area A surrounded by the light transmission holes H, and the area R is smaller than the arrangement area A, which helps to prevent an insufficient number of light transmission holes H within the area R due to assembly tolerances, ensuring proper light reception by the receiver 232. In one embodiment, if there are no assembly tolerance issues, the area where the reception range of the receiver projected onto the reflective film can has a same size as the arrangement area surrounded by the light transmission holes.

In this embodiment, the arrangement area A of the reflective film 22 is located in the central area of the main portion 221 of the reflective film 22, and the light transmission holes H are provided in the arrangement area A of the main portion 221, which enables the receiver 232 to achieve a balanced capability to receive light from different directions.

Note that the position of the arrangement area A of the reflective film 22 is not limited to being located in the central area of the main portion 221 of the reflective film 22. Instead, it can be adjusted to other areas of the main portion 221 of the reflective film 22 according to actual requirements.

In this embodiment, the arrangement area A is a polygonal area, where two of the light transmission holes H are located outside the arrangement area A and are located at two opposite sides of the arrangement area A, while the others are located in the arrangement area A, which helps to identify the orientation of the reflective film 22, facilitating the assembly process.

Note that the arrangement area A is not limited to being a polygonal area and may be modified to an area of other shapes.

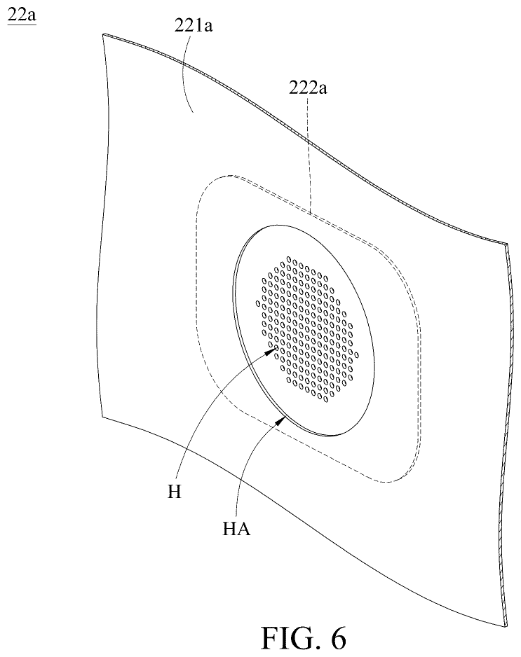

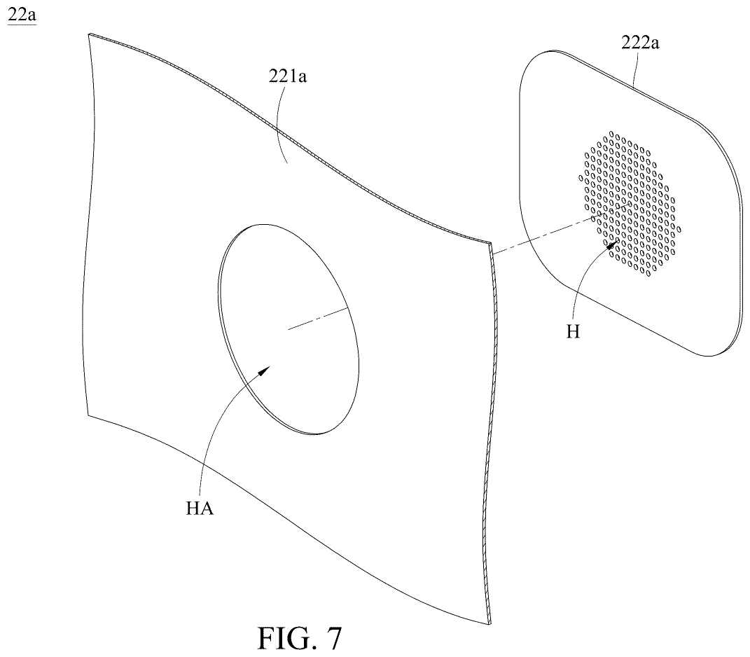

Referring to FIGS. 6 and 7, FIG. 6 is a partial perspective view of a reflective film according to a second embodiment of the disclosure, and FIG. 7 is a partial exploded view of the reflective film in FIG. 6.

The reflective film 22a of this embodiment is similar to the reflective film 22 of the previous embodiment, and can replace the reflective film 22 of the previous embodiment. The following descriptions mainly introduce the difference between them while the same part will not be repeatedly introduced hereinafter.

In this embodiment, the reflective film 22a includes a main portion 221a and an attachment portion 222a. The main portion 221a is provided with a through hole HA. The through hole HA is, for example, located in a central area of the main portion 221a. The attachment portion 222a is attached on the main portion 221a, and light transmission holes H of the reflective film 22a are provided on the attachment portion 222a. The light transmission holes H correspond to the through hole HA of the main portion 221a.

According to the display device and the optical module as discussed in the above embodiments, the receiver assembly is disposed in the casing assembly and located at one side of the reflective film located farther away from the optical assembly, and the receiver assembly corresponds to the light transmission holes in the visible area of the reflective film where the window is projected. This configuration allows the receiver assembly to receive light that penetrates through the display panel, the optical assembly and the reflective film. As a result, the receiver assembly is not installed on the bezel of the casing assembly, and thus there is no need to increase the width of the bezel to accommodate the receiver assembly, which contributes to achieve the narrow bezel requirement of the display device.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. A display device, comprising:
a casing assembly, comprising a window surrounded by a bezel;
an optical module, disposed in the casing assembly and comprising:
an optical assembly;
a reflective film, located farther away from the window than the optical assembly, wherein the reflective film is provided with a plurality of light transmission holes, and the plurality of light transmission holes is located in a visible area where the window is projected; and
a receiver assembly, located at one side of the reflective film located farther away from the optical assembly, wherein the receiver assembly corresponds to the plurality of light transmission holes; and
a display panel, disposed in the casing assembly and located closer to the window than the optical assembly.

2. The display device according to claim 1, wherein the plurality of light transmission holes are located in a central area of the reflective film.

3. The display device according to claim 1, wherein the plurality of light transmission holes are arranged in an array.

4. The display device according to claim 3, wherein a distance between centers of two of the plurality of light transmission holes located closest to each other is not greater than 1.0 mm.

5. The display device according to claim 3, wherein hole diameters of the plurality of light transmission holes are not smaller than 0.6 mm and are not greater than 0.8 mm.

6. The display device according to claim 1, wherein an area where a reception range of the receiver assembly is projected onto the reflective film is overlapped with an area surrounded by the plurality of light transmission holes, and the area where the reception range of the receiver assembly is projected onto the reflective film is smaller than the area surrounded by the plurality of light transmission holes.

7. The display device according to claim 1, wherein the reflective film comprises a main portion and an attachment portion, the main portion is provided with a through hole, the attachment portion is attached on the main portion, the plurality of light transmission holes are provided on the attachment portion, and the plurality of light transmission holes correspond to the through hole.

8. The display device according to claim 1, wherein the reflective film comprises a main portion, and the plurality of light transmission holes are directly provided on the main portion.

9. The display device according to claim 1, wherein the plurality of light transmission holes surround an arrangement area on the reflective film, the arrangement area is a polygonal area, two of the plurality of light transmission holes are located outside the arrangement area and are located at two opposite sides of the arrangement area, and the others of the plurality of light transmission holes are located in the arrangement area.

10. The display device according to claim 1, wherein the casing assembly comprises a casing and a support component fixed in the casing, the support component comprises a first surface, a second surface and a through hole, the first surface faces the window and faces away from the second surface, the through hole penetrates through the first surface and the second surface, the reflective film is disposed on the first surface of the support component, the optical module further comprises a mount bracket, the receiver assembly is fixed to the second surface of the support component via the mount bracket, and the receiver assembly corresponds to the plurality of light transmission holes of the reflective film through the through hole.

11. The display device according to claim 1, wherein the receiver assembly is an infrared receiver assembly.

12. An optical module, comprising:
an optical assembly;
a reflective film, located at one side of the optical assembly, wherein the reflective film is provided with a plurality of light transmission holes, and the plurality of light transmission holes are located in a visible area of the reflective film; and
a receiver assembly, located at one side of the reflective film located farther away from the optical assembly, wherein the receiver assembly corresponds to the plurality of light transmission holes.

13. The optical module according to claim 12, wherein the plurality of light transmission holes are located in a central area of the reflective film.

14. The optical module according to claim 12, wherein the plurality of light transmission holes are arranged in an array.

15. The optical module according to claim 14, wherein a distance between centers of two of the plurality of light transmission holes located closest to each other is not greater than 1.0mm.

16. The optical module according to claim 14, wherein hole diameters of the plurality of light transmission holes are not smaller than 0.6 mm and are not greater than 0.8 mm.

17. The optical module according to claim 12, wherein an area where a reception range of the receiver assembly is projected onto the reflective film is overlapped with an area surrounded by the plurality of light transmission holes, and the area where the reception range of the receiver assembly is projected onto the reflective film is smaller than the area surrounded by the plurality of light transmission holes.

18. The optical module according to claim 12, wherein the reflective film comprises a main portion and an attachment portion, the main portion is provided with a through hole, the attachment portion is attached on the main portion, the plurality of light transmission holes are provided on the attachment portion, and the plurality of light transmission holes correspond to the through hole.

19. The optical module according to claim 12, wherein the reflective film comprises a main portion, and the plurality of light transmission holes are directly provided on the main portion

20. An optical module, used to be cooperated with a receiver assembly, comprising:
an optical assembly; and
a reflective film, located at one side of the optical assembly, wherein the reflective film is provided with a plurality of light transmission holes, the plurality of light transmission holes are located in a visible area of the reflective film, and the receiver assembly is used to receive light through the plurality of light transmission holes.
